(19) United States
(12) Patent Application Publication
(10) Pub. No.: US 2006/0176095 A1
(43) Pub. Date: Aug. 10, 2006

(54) Cycle staging latch with dual phase dynamic outputs for hit logic compare

(75) Inventors: Yuen H. Chan, Poughkeepsie, NY (US); Timothy J. Charest, West Hurley, NY (US); Rajiv V. Joshi, Yorktown Heights, NY (US)

Correspondence Address: Lynn L. Augspurger;IBM Corporation, 2455 South Road, P386, Poughkeepsie, NY, 12601, US

(73) Assignee: International Business Machines Corporation, Armonk, NY (US)

(21) Appl. No.: 11/054,310

(22) Filed: Feb. 9, 2005

(51) Int. Cl. H03K 3/037

(52) U.S. Cl. 327/218

(57) ABSTRACT

An output L1/L2 staging latch has dual rail inputs that up date the state of the L1 latch whenever the inputs are valid. Static outputs of the L1 latch are latched into the L2 by the L2 clock signal. The L2 latch has a static output that is available immediately, and a dual rail dynamic output whose timing is controlled by a clock signal.

### CROSS-REFERENCE TO RELATED APPLICATIONS

This application contains subject matter that is related to the subject matter of the following co-pending applications, each of which is assigned to the same assignee as this application, International Business Machines Corporation of Armonk, N.Y. Each of the below listed applications is hereby incorporated herein by reference in its entirety: High Speed Domino Bit Line Interface Early Read and Noise Suppression, Attorney Docket POU9 2004 0217; Global Bit Select Circuit With Dual Read and Write Bit Line Pairs, Attorney Docket POU9 2004 0214; Local Bit Select Circuit With Slow Read Recovery Scheme, Attorney Docket POU9 2004 0224; Global Bit Line Restore Timing Scheme and Circuit, Attorney Docket POU9 2004 1234; Local Bit Select With Suppression, Attorney Docket POU9 2004 0246.

### BACKGROUND OF THE INVENTION

1. Field of the Invention

This invention relates to cycle staging latches, and more particularly to and L1/L2 cycle staging latch that allows for variability in the timing of the input to the L1 latch while the timing of the firing of the L2 latch remains fixed.

2. Description of Background

As will be appreciated by those skilled in the art, a latch circuit of the type contemplated by this invention has a data and a clock input. The data input state at the leading clock edge is transferred to the latch output. The output state is retained after the trailing edge of the clock, independent of changes in the input data. A common approach to memory logic uses one latch L1 as a master latch and another latch L2 as a slave latch, with the output of L1 coupled to the input of its associated L2 latch. The latches are connected in series to from a chain and separate clock signals (C1 and C2 respectively) are used to clock the L1 latches and the L2 latches. As will also be appreciated by those skilled in the art, one L2 latch is associated as a slave with each L1 latch in order to allow scan test.

With CMOS technologies getting scaled down to smaller dimensions, tracking of signals in time from transistor to transistor is getting harder to control. For example, signals being sent from one macro (e.g. a D-Cache Directory (DDIR)) to be compared to signals from another macro (e.g. results from the DDIR array). With the distances between the macros relatively large, there is problem that too much variability in signal timing will be introduced into the critical path through parameters such as mismatch of channel lengths, threshold voltages, and timing delays.

### SUMMARY OF THE INVENTION

One object of this invention is the provision of a staging latch which allows for variability for the L1 stage of the latch contents coming from ones macro while allowing the L2 stage to be fired at the appropriate time as needed in order for its contents to be properly compared with the contents from another macro.

Another object of the invention is the provision of a staging latch in which the output from the L2 stage is converted from static to dual rail dynamic signals, so that they can be used to drive high speed dynamic comparators down stream.

Briefly, this invention contemplates the provision an output L1/L2 staging latch in which dual rail inputs up date the state of the L1 latch whenever the inputs are valid. The static outputs of the L1 latch are latched into the L2 by the L2 clock signal. The L2 latch has a static output that is available immediately, and a dual rail dynamic output whose timing is controlled by a clock signal.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIGS. 1 is a schematic diagram of one embodiment of an L1/L2 staging latch in accordance with this invention.

FIGS. 2 and 3 each respectively comprise different halves on an expanded scale of the drawing of FIG. 1.

FIG. 4 is a timing diagram for the L1/L2 staging latch shown in FIGS. 1, 2 and 3.

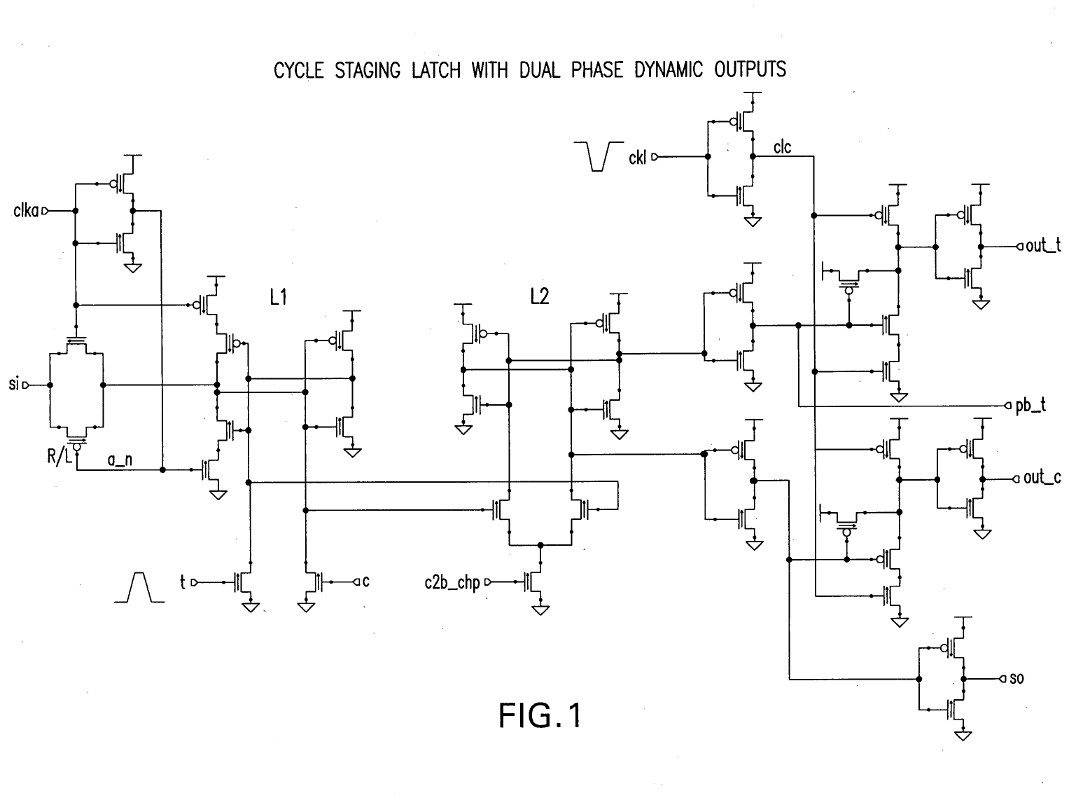

### DETAIL DESCRIPTION OF THE INVENTION

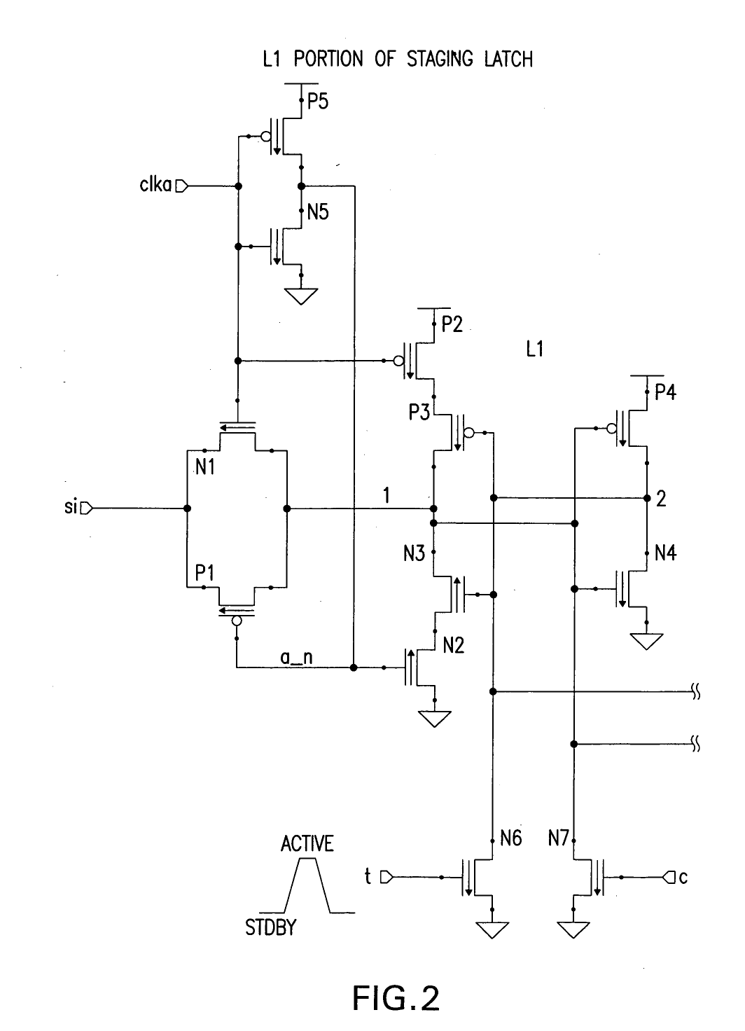

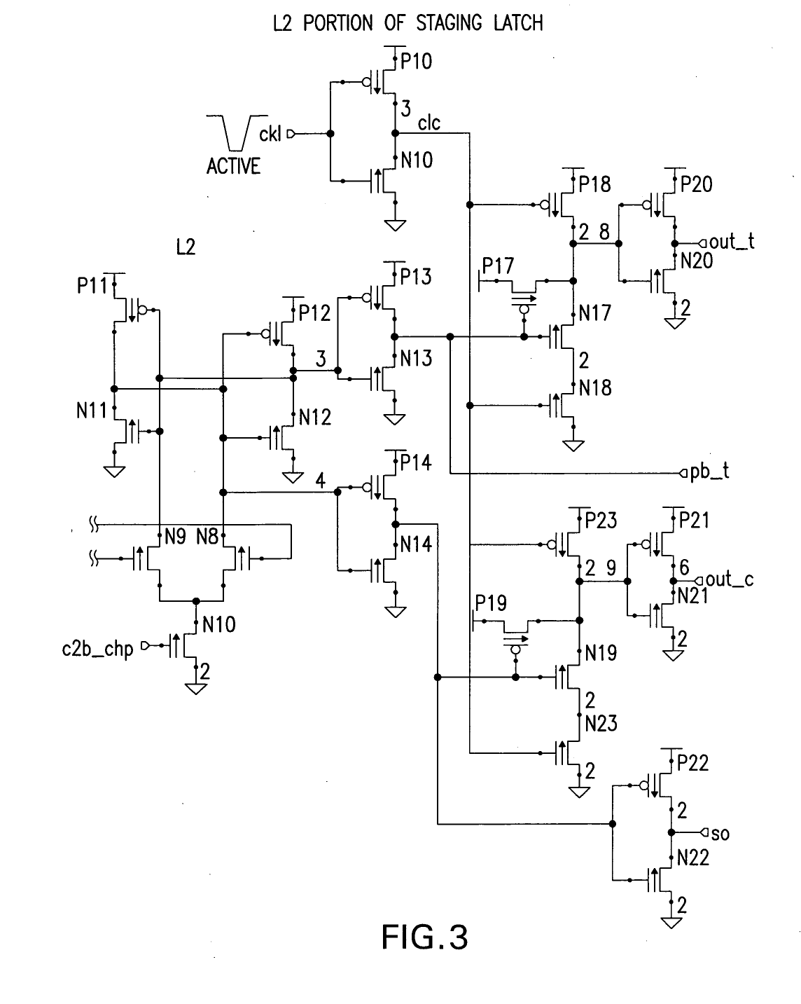

Referring now to the Figures, because of size, the L1 stage of the L1/L2 staging latch is shown in FIG. 2 and the L2 stage is shown in FIG. 2. The inputs to the L1 latch are true “t” and its complement ‘c’ from a memory array (not shown). These are dual-rail inputs, meaning either ‘t’ or ‘c’ are active but not both. When the memory array is in a standby mode, both ‘t’ and ‘c’ are off so the contents of the L1 latch are not disturbed. When valid contents are presented from the array, either ‘t’ will turn on transistor N6 to pull down node ‘2’ or, ‘c’ will turn on transistor N7 to pull down node ‘1’. The L1 latch can also be scanned through the ‘si’ port when ‘clka’ is high. The nodes ‘1’ and ‘2’ are static nodes and are coupled as inputs to the gates of transistors N8 and N9 respectively of the L2 latch.

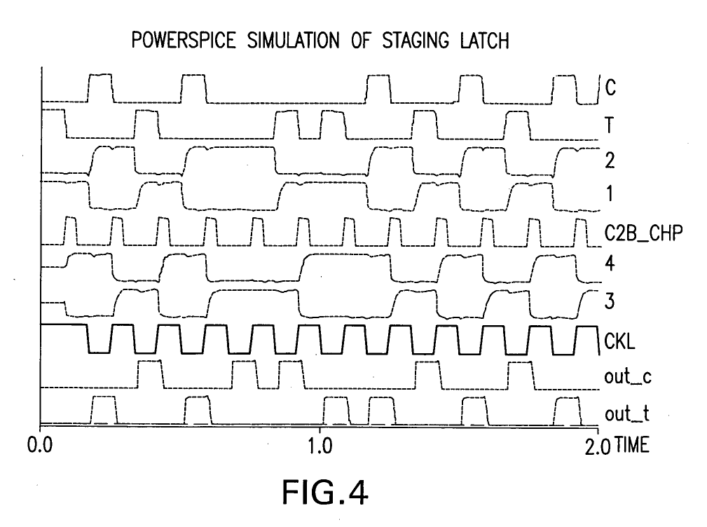

Either N8 or N9 will be turned on when the L2 clock signal ‘c2b_chp’ is active high. When ‘c2b_chp’ is active, the contents of the L1 will then be stored in the L2 latch circuit comprised of transistors P11, N11 and P12, N12. One side of the latch may be pulled low depending on the present content in the L2. Nodes ‘3’, ‘4’, ‘pb_t’ and ‘so’ are static signals with the new content of the L2, representing the data from the memory array. When the local clock ‘ckl’ is active (low) only ‘out_t’ or ‘out_c’ will be active (high) sending the contents of the array to the compare circuitry. The dual-rail output allows the fastest possible compare function to be used. FIG. 4 shows the relative timing for the signals described above.

In operation, there are several advantages to this staging latch. First, the contents of the L1 are updated whenever the inputs from the memory array are valid. The L1 is essentially in flush mode waiting for either ‘t’ or ‘c’ in order to change the contents of the L1 latch. Any variability in memory array timing will not affect functionality. The L2 clock ‘c2b_chp’ will flush the static outputs as soon as it's active. Thus, any function not requiring dual-rail outputs, such as scanning or misr are available immediately. In addition, the dual-rail outputs ‘t’ and ‘c’ of L2 can be controlled to fire after the contents are available from the from the macro with which the dual rail outputs ‘t’ and ‘c’ are to be compared. The ‘ckl’ can be controlled through a variable timing block (via gptr mode bits) to move the timing of the dual rail L2 outputs. If the contents arrive at the compare function to soon, a false miss could occur which would mask a valid hit. This staging and the ability to control it timing is critical to proper functionality. It also allows for a very fast design with a margin of safety.

While the preferred embodiment of the invention has been described, it will be understood that those skilled in the art, both now and in the future, may make various improvements and enhancements which fall within the scope of the claims which follow. These claims should be construed to maintain the proper protection for the invention first described.

1-3. (canceled)

4. An L1-L2 cycle staging latch for providing dual rail dynamic outputs, comprising in combination:
an L1 latch having dual rail input terminals and a dual rail output terminals;
an L2 latch having dual rail input terminals connected to said dual rail output terminals of said L1 latch, dynamic dual rail output terminals, and a clock input terminal;
said L1 latch generating a dual rail static output at said dual rail output terminals whenever an input to its dual rail input terminals is valid; and
said L2 latch generating a dual rail dynamic output at its dynamic dual rail output terminals in response to an input coupled to its dual rail input terminals from said L1 latch in combination with an active state of a clock signal coupled to its clock input terminal.

5. An L1-L2 cycle staging latch for providing dual rail dynamic outputs as in claim 4 in which the L1 latch includes a scan in terminal and a scan clock terminal.

6. An L1-L2 cycle staging latch for providing dual rail dynamic outputs as in claim 4 in which the L2 latch includes a scan out terminal.

7. An L1-L2 cycle staging latch for providing dual rail dynamic outputs as in claim 5 in which the L2 latch includes a scan out terminal.

8. An L1-L2 cycle staging latch for providing dual rail dynamic outputs as in claim 6 in which the L2 latch scan out terminal is connected to an L2 latch node whose state is established by an input coupled to the dual rail inputs of the L2 latch.

9. An L1-L2 cycle staging latch for providing dual rail dynamic outputs as in claim 7 in which the L2 latch scan out terminal is connected to an L2 latch node whose state is established by an input coupled to the dual rail inputs of the L2 latch.

10. An L1-L2 cycle staging latch for providing dual rail dynamic outputs as in claim 4 wherein said L2 latch generates as static output.

11. An L1-L2 cycle staging latch for providing dual rail dynamic outputs as in claim 5 wherein said L2 latch generates as static output.

12. An L1-L2 cycle staging latch for providing dual rail dynamic outputs as in claim 6 wherein said L2 latch generates as static output.

13. An L1-L2 cycle staging latch for providing dual rail dynamic outputs as in claim 7 wherein said L2 latch generates as static output.

14. A method for operating an L1-L2 cycle staging latch including the steps of:
updating the output of the L1 latch whenever inputs to the L1 latch are valid;
transferring the updated output of the L1 latch to the input of the L2 latch;
generating a dual rail output from the L2 latch;
controlling the timing of the output of the L2 latch in response to an input to said L2 latch.

14. A method for operating an L1-L2 cycle staging latch as in claim 13 wherein said controlling step is controlled by a clock signal input to said L2 latch.

15. A method for operating an L1-L2 cycle staging latch as in claim 13 including the further step of generating a static output from said L2 latch.

16. A method for operating an L1-L2 cycle staging latch as in claim 14 including the further step of generating a static output from said L2 latch.

17. A cycle staging latch system for providing dual rail dynamic outputs, comprising in combination:
a first means for latching having dual rail input terminals and a dual rail output terminals;
a second means for latching having dual rail input terminals connected to said dual rail output terminals of said first means, dynamic dual rail output terminals, and a clock input terminal;
said first means generating a dual rail static output at said dual rail output terminals whenever an input to its dual rail input terminals is valid; and
said second means generating a dual rail dynamic output at its dynamic dual rail output terminals in response to an input coupled to its dual rail input terminals from said first means in combination with an active state of a clock signal coupled to its clock input terminal.

18. A cycle staging latch for providing dual rail dynamic outputs as in claim 17 in which the first means includes a scan in terminal and a scan clock terminal.

19. A cycle staging latch for providing dual rail dynamic outputs as in claim 18 in which the second means includes a scan out terminal.

20. A cycle staging latch for providing dual rail dynamic outputs as in claim 19 in which the second means includes a scan out terminal.

21. A cycle staging latch for providing dual rail dynamic outputs as in claim 18 in which the second means scan out terminal is connected to a latch node whose state is established by an input coupled to the dual rail inputs of the second means.

22. A cycle staging latch for providing dual rail dynamic outputs as in claim 18 wherein said second means generates a static output.

23. A cycle staging latch for providing dual rail dynamic outputs as in claim 19 wherein said second means generates a static output.
